(19) United States
(12) Patent Application Publication
(10) Pub. No.: US 2007/0144775 A1
(43) Pub. Date: Jun. 28, 2007

(54) Substrate inspection method, printed-wiring board, and electronic circuit device

(76) Inventor: Kenji Hasegawa, Ome-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/635,407

(22) Filed: Dec. 6, 2006

(30) Foreign Application Priority Data
Dec. 22, 2005 (JP) 2005-369481

(51) Int. Cl. H05K 1/11; H01R 12/04

(52) U.S. Cl. 174/262

(57) ABSTRACT

According to one embodiment, there is provided a substrate inspection method including forming a film over an opening portion of a blind via hole formed in a printed-wiring board, and heating the printed-wiring board. Based on a variation in the shape of the film, it is possible to determine a defective blind via hole.

### CROSS-REFERENCE TO RELATED APPLICATIONS

This application is based upon and claims the benefit of priority from Japanese Patent Application No. 2005-369481, filed Dec. 22, 2005, the entire contents of which are incorporated herein by reference.

### BACKGROUND

1. Field

One embodiment of the invention relates to a substrate inspection method, a printed-wiring board, and an electronic circuit device which are applied to quality control of a substrate having a blind via hole.

2. Description of the Related Art

A printed-wiring board having a multilayer structure, which is referred to as a build-up wiring board, is used for an electronic circuit device such as a personal computer. A lot of blind via holes are used in a printed-wiring board. A blind via hole is formed by producing a hole in a surface layer by, for example, laser irradiation, plating the hole, and coupling a pattern on the surface layer to a pattern of an inner layer. In order to achieve a stable operation of a product, it is necessary that the electrical conductivity of the blind via hole is maintained by sufficient plating.

As for quality control techniques for printed-wiring boards with blind via holes, there is a technique which confirms the above-mentioned electrical conductivity by a test coupon (for example, see Japanese Patent Application KOKAI Publication No. 2000-223840).

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary diagram showing an exemplary structure of a test coupon according to an embodiment of the invention;

FIG. 2 is an exemplary diagram showing a state of the test coupon according to the embodiment after heat treatment;

FIG. 3 is an exemplary diagram showing a state of the test coupon according to the embodiment before the heat treatment and a defective blind via hole therein;

FIG. 4 is an exemplary diagram showing a state of the test coupon according to the embodiment after the heat treatment and the defective blind via hole;

FIG. 5 is an exemplary diagram for explaining defective solder bonding due to the defective blind via hole; and

FIG. 6 is an exemplary diagram for explaining the defective solder bonding due to the defective blind via hole.

### DETAILED DESCRIPTION

Various embodiments according to the invention will be described hereinafter with reference to the accompanying drawings. In general, according to one embodiment of the invention, there is provided a substrate inspection method including: forming a film over an opening portion of a blind via hole formed in a printed-wiring board; and heating the printed-wiring board.

When heat is applied to a printed-wiring board having a blind via hole, if there is a defective portion in the blind via hole such as a crack, a pinhole, defective plating, etc., a gas in a base material including an insulating material flows out via the defective portion. One embodiment of the present invention is directed to capture and use the gas which flows out into the blind via hole, thereby easily detecting a defect in the blind via hole which defect is overlooked in a conductivity test.

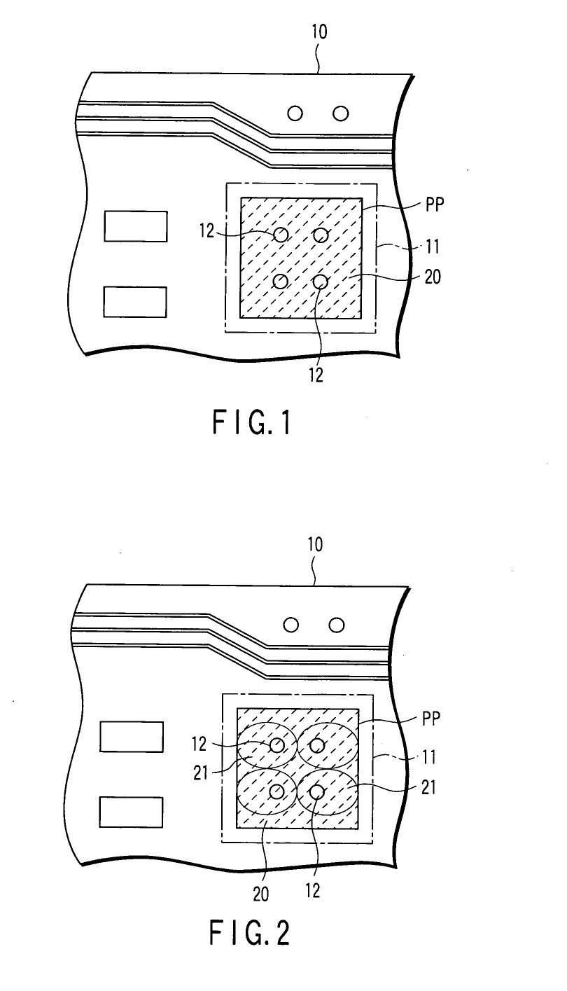

FIG. 1 shows a part of elements which realize a substrate inspection method, a printed-wiring board, and an electronic circuit device according to an embodiment of the invention.

In FIG. 1, a printed-wiring board 10 forms a build-up multilayer wiring board. A lot of wiring patterns, through holes, blind via holes, lands, pads, etc. for connecting a circuit of the printed-wiring board 10 to a circuit of an electronic component to be mounted are formed in a surface layer and an inner layer of the printed-wiring board 10. Additionally, a test coupon 11 for testing defective blind via holes is provided in a part of the printed-wiring board 10. Alternatively, the test coupon 11 may be provided on a part of the printed-wiring board 10.

The test coupon 11 includes a plain pattern PP in the surface layer. Four blind via holes 12, 12, . . . are formed between the plain pattern PP and an inner layer pattern (Pa). Each of the via holes 12, 12, . . . , which are provided in the test coupon 11, is formed by a hole forming process by laser irradiation and a plating process similar to those for other blind via holes provided in the printed-wiring board 10. In this embodiment, the test coupon 11 provided with the four blind via holes is shown as an example. However, the test coupon 11 may be any one of, for example, a test coupon provided with a single blind via hole, a test coupon provided with five or more blind via holes, or a test coupon provided with blind via holes and other conductors to be tested, such as a test coupon provided with an arbitrary number of blind via holes and through holes, etc. Each of the blind via holes 12, 12, . . . provided in the test coupon 11 is a blind via hole without a circuit function (not serving as a functional circuit) and provided only for testing.

A heat-resistant film 20 is applied to the plain pattern formed on the surface layer of the test coupon 11, which is provided with the blind via holes 12, 12, . . . . A film material having adhesiveness and heat-resisting properties which withstands, for example, a reflowing process, or a heat-resistant sheet material having elasticity may be used for the film 20. Alternatively, a dry film which is left without being separated at the time of pattern forming may also be used for the film 20. Further, instead of these films or sheet materials, a heat-resistant adhesive, a semi-cured resin, a metal film including a solder film, etc. may be used for the film 20.

By applying the above-mentioned film 20, an opening of each of the blind via holes 12, 12, . . . provided in the test coupon 11 is covered with the film 20. Thus, the openings of the blind via holes are sealed by the film 20, and a space is formed where the openings of the blind via holes are closed.

With a normal circuit board manufacturing technique, various kinds of electronic components, which form an electronic circuit device, are mounted on the printed-wiring board 10 including the test coupon 11 to which the film 20 is applied. The printed-wiring board 10 mounting the electronic components is conveyed to a reflow oven and subjected to heat treatment (solder reflowing process). As a result, a printed-circuit board (PCB) whose circuit pattern is connected to a circuit of the mounted electronic component, or an electronic circuit device including a functional circuit is manufactured.

In the above-mentioned heat treatment (solder reflowing process), when the printed-wiring board 10 including the test coupon 11 covered with the film 20 is heated, if a defective blind via hole exists which includes a defective portion such as a crack, a pinhole, defective plating, etc., a gas generated from a base material including an insulating material flows out into the above-mentioned space, which is obtained by sealing the opening of the defective via hole. As a consequence, a portion of the film 20 sealing the opening is deformed. In this embodiment, the portion sealing the opening is bloated and raised.

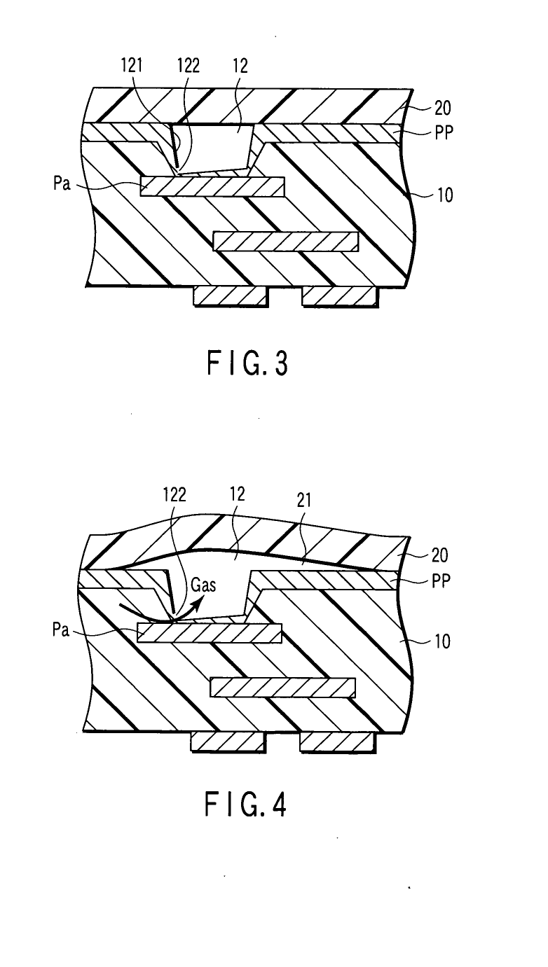

FIG. 2 shows such a state. FIG. 2 shows an exemplary case where all of the blind via holes 12, 12, . . . provided in the test coupon 11 are defective via holes. Additionally, FIGS. 3 and 4 show transition of the state of the film 20 sealing the openings.

As shown in FIG. 2, the gas generated from the base material including the insulating material flows out into the space which is obtained by sealing the openings of the defective blind via holes. As a result, the film 20 is deformed at portions sealing the openings. In the embodiment shown in FIG. 2, the portions sealing the openings of the blind via holes 12 are bloated, and convex portions 21 are formed. By observing the convex portions 21 formed by bloating of the film 20, it is possible to confirm the presence of defective blind via holes.

FIG. 3 shows an exemplary state of the test coupon 11 before heat treatment. The test coupon 11 includes a defective blind via hole formed therein and is covered with the film 20. FIG. 4 shows a state of the test coupon 11 after the heat treatment.

FIG. 3 shows a defective case where a barrel crack 122 exists in a side-wall copper film 121 of the blind via hole 12 which is formed between the plain pattern PP in the surface layer and the inner layer pattern Pa. When the test coupon 11 including such a defective blind via hole 12 is heated in a reflow process, as shown in FIG. 4, a gas generated from the base material including the insulating material flows out into the space, which is obtained by sealing the opening of the defective blind via hole. The gas flows out into the space through a portion without the copper film, which portion is created by the barrel crack 122. As a result, the film 20 is deformed at the portion sealing the opening, and the convex portion 21 is formed by the portion of the film 20 above the defective blind via hole 12.

By observing the deformed state of the film 20 by visual observation, or by an optical measuring means, etc., it is possible to confirm the presence of the defective blind via hole. For example, the film 20 may be colored such that the raised portion is visually distinguished from a portion contacting the plain pattern PP, when the film 20 is raised from the plain pattern PP of the test coupon 11. In this case, it is possible to more simplify a visual inspection of a defective blind via hole. Further, in the case where a solder film or other metal film is used, it is possible to easily confirm the presence of a defective blind via hole by observing a deformed state of the surface by, for example, an optical measuring means, etc.

Here, when the convex portion 21 is formed in the film 20 above, for example, one (or two) or more blind via holes among the four blind via holes 12, 12, . . . provided in the test coupon 11, the blind via holes forming a functional circuit of the printed-wiring board 10 are regarded as defective blind via holes having a defective factor which may cause disconnection afterward, even if the blind via holes pass a conductivity test. Further, the causes of the defectiveness of the blind via holes regarded as defective are analyzed, and the result of the analysis is reflected to a manufacturing process thereafter. By adopting such measures, it is possible to control the quality of the printed-wiring board 10, and to improve the quality of the printed-wiring board 10. For example, as to manufacturing of a printed-wiring board or an electronic circuit device which is used in an airplane, a space satellite, etc. and requires a high reliability, it is possible to conduct a more accurate test of defective blind via holes by providing more blind via holes in the test coupon 11. For instance, in the case where the test coupon 11 is provided which includes 10 or more blind via holes 12, 12, . . . covered with the film 20, and after reflowing, when deformation is observed with respect to any one of the blind via holes 12, 12, . . . , the blind via hole is regarded as defective based on determination that there is a high possibility of the presence of a blind via hole having a defective factor which may cause disconnection afterward. Accordingly, it is possible to perform a highly accurate test of defective blind via holes.

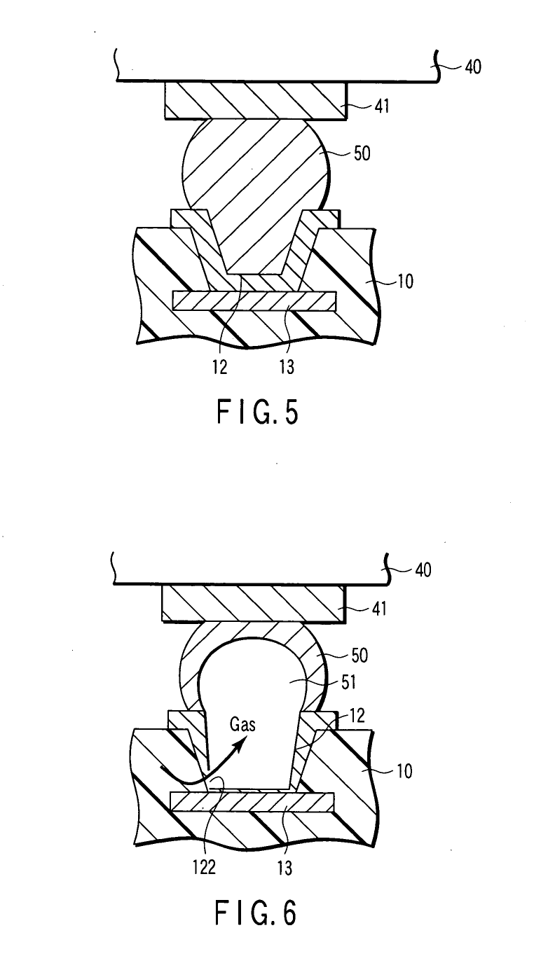

In the case where an electronic component, forming an electronic circuit device, is soldered to the printed-wiring board 10 including a defective blind via hole as mentioned above, the electronic component is soldered in a state which is not preferable as a product. An example of such a case will be described with reference to FIGS. 5 and 6. It should be noted that, in FIGS. 5 and 6, those parts corresponding to the same parts in FIGS. 3 and 4 are designated by the same reference numerals.

FIG. 5 shows a state of a soldered potion in the case where an electronic component, forming an electronic circuit device, is soldered to the printed-wiring board (circuit board) 10 via a normal blind via hole without a defective portion, such as a crack, a pinhole, defective plating, etc. as mentioned above. FIG. 6 shows a state of a soldered portion in the case where an electronic component, forming an electronic circuit device, is soldered to the printed-wiring board (circuit board) 10 via a defective blind via hole having a defective portion, such as a crack, a pinhole, defective plating, etc. In FIGS. 5 and 6, the cases are shown where a pad 41 provided on an electronic component (e.g., a BGA semiconductor package) 40 is connected to an inner layer pattern 13 of the circuit board 10 via a solder ball 50 and the blind via hole 12.

In the case where the electronic component 40 is soldered to the normal blind via hole 12 without a defective portion, the gas generated from the base material does not flow into the blind via hole 12 at the time of heating. Thus, as shown in FIG. 5, the solder ball 50 is completely filled with solder (solid state), and no void is formed in the solder ball 50. In this case, the electronic component 40 is firmly soldered to the circuit board 10 with respect to a deforming force, pressure, etc., which is externally applied to the electronic component 40 or the circuit board 10, and a circuit of the electronic component 40 is connected to the circuit board 10 in a stable state over a long period of time.

On the other hand, in the case where the electronic component 40 is soldered to the defective blind via hole 12 with a defective portion such as a crack, a pinhole, defective plating, etc., the gas generated from the base material flows into the blind via hole at the time of heating. Hence, as shown in FIG. 6, a void 51 is formed in the solder ball 50 due to accumulation of the gas. In this case, the electronic component 40 is soldered to the circuit board 10 in a state highly fragile with respect to a deforming force, pressure, etc., which is externally applied to the electronic component 40 or the circuit board 10, and a circuit of the electronic component 40 is soldered to the circuit board 10 in a state which lacks reliability.

It is difficult to expect a stable operation for a long period of time of an electronic circuit device including circuits which are connected to each other via such a solder ball 50 with the void 51. As a result, such an electronic circuit device becomes a product with low reliability.

Therefore, by conducting a test of a defective blind via hole using the test coupon 11 according to the above-mentioned embodiment, it is possible to manufacture an electronic circuit device with high reliability, while eliminating a defective product including circuits connected to each other by soldering which lacks in reliability as shown in FIG. 6. Electronic circuit devices manufactured by applying an embodiment of the invention thereto can be provided as various functional circuit devices requiring a high reliability and incorporated in, for example, a communication satellite as well as functional circuit devices incorporated in general-purpose personal computer, mobile terminal, etc.

The above-mentioned test coupon 11 may be cut off from a circuit board after the test of defective via holes. However, by leaving the test coupon 11 as is, the test coupon 11 can be used for product control. For example, in an electronic circuit device manufactured by the above-mentioned manufacturing process, by leaving the test coupon 11 whose surface is covered with a film as is, it is possible to effectively utilize the test coupon 11 for an endurance test of a product, quality control before and after product shipment, etc. by using the test coupon 11 as a quality control pattern.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A substrate inspection method, comprising:
forming a film over an opening portion of a blind via hole formed in a printed-wiring board; and
heating the printed-wiring board.

2. The substrate inspection method according to claim 1, wherein the film is formed over a test coupon in which the blind via hole is formed.

3. The substrate inspection method according to claim 2, wherein a plurality of blind via holes are formed in the test coupon.

4. The substrate inspection method according to claim 3, wherein the film comprises one of a dry film, a heat-resistant film, and a heat-resistant sheet member.

5. The substrate inspection method according to claim 3, wherein the film comprises one of a heat-resistant adhesive and a heat-resistant semi-cured resin.

6. The substrate inspection method according to claim 3, wherein the film comprises one of a solder film and a metal film.

7. A printed-wiring board, comprising:
a test coupon including a blind via hole; and
a film covering an opening portion of the blind via hole.

8. The printed-wiring board according to claim 7, wherein a plurality of blind via holes are provided in the test coupon.

9. The printed-wiring board according to claim 7, wherein the film comprises one of a heat-resistant film, a heat-resistant semi-cured resin, and a metal film.

10. An electronic circuit device, comprising:
a printed-wiring board;
a test coupon including a blind via hole and provided in the printed-wiring board; and
a film covering an opening portion of the blind via hole.
